(19) United States
(12) Patent Application Publication
(10) Pub. No.: US 2025/0118643 A1
(43) Pub. Date: Apr. 10, 2025

(54) Semiconductor Device and Method of Inhibiting Creep of Underfill Material on Back Surface of Semiconductor Die

(71) Applicant: STATS ChipPAC Pte. Ltd., Singapore (SG)

(72) Inventors: Yi Jing Eric Chong, Singapore (SG); Marites Roque, Singapore (SG); Rowena Zarate, Singapore (SG); Linda Pei Ee Chua, Singapore (SG); Kai Chong Chan, Singapore (SG)

(73) Assignee: STATS ChipPAC Pte. Ltd., Singapore (SG)

(21) Appl. No.: 18/483,433

(22) Filed: Oct. 9, 2023

(51) Int. Cl. H01L 23/498; H01L 23/00; H01L 25/065

(52) U.S. Cl. CPC H01L 23/49822; H01L 23/49816; H01L 24/13; H01L 24/29; H01L 24/97; H01L 25/0657; H01L 2224/13024; H01L 2224/13025; H01L 2224/29022; H01L 2224/29025; H01L 2224/97; H01L 2225/06517; H01L 2924/15311

(57) ABSTRACT

A semiconductor device has a first substrate with a surface. A thickness of the first substrate is less than 120 micrometers. The surface undergoes a grinding operation. The surface of the first substrate is then polished to produce a polished surface. The first substrate is singulated into a plurality of semiconductor die. The semiconductor die is over an interposer. The interposer has a second substrate and a conductive via formed through the second substrate. The interposer further has a first insulating layer formed over a first surface of the second substrate, first conductive layer formed over the first surface, second insulating layer formed over a second surface of the second substrate, second conductive layer formed over the second surface, and bump formed over the second conductive layer. An underfill material is deposited around the semiconductor die. The polished surface inhibits progression of the underfill material onto the polished surface.

### FIELD OF THE INVENTION

The present invention relates in general to semiconductor devices and, more particularly, to a semiconductor device and method of inhibiting the creep of underfill material onto a back surface of a semiconductor die.

### BACKGROUND OF THE INVENTION

Semiconductor devices are commonly found in modern electrical products. Semiconductor devices perform a wide range of functions, such as signal processing, high-speed calculations, transmitting and receiving electromagnetic signals, controlling electrical devices, photo-electric, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

A semiconductor wafer typically contains a plurality of semiconductor die. The semiconductor die can perform a variety of functions including a micro electrical mechanical system (MEMS). The MEMS device can have a sensor or other transducer formed on a back surface and active sensor interface components formed on an active surface. The back surface may undergo a grinding operation to planarize the surface. However, the grinding creates grooves, scratches, and other damage in the back surface. The semiconductor die are singulated and can be mounted to an interposer for electrical interconnect. An underfill material is deposited around the semiconductor die for environmental protection. However, the underfill material is known to creep onto the back surface of the semiconductor die and get trapped within the grooves, scratches, and other damage on the back surface. The creeping underfill material can damage the sensor, resulting in lower yields and higher manufacturing costs.

### BRIEF DESCRIPTION OF THE DRAWINGS

FIGS. 1a-1i illustrate a semiconductor wafer with a plurality of semiconductor die undergoing a grinding operation followed by a polishing operation;

FIGS. 2a-2d illustrate a formation of an interconnect interposer;

FIGS. 3a-3f illustrate disposing the semiconductor die over the interposer and depositing underfill material around the semiconductor die;

FIG. 4 illustrates an interconnect structure formed over the interposer and the underfill material being less than a height of the interconnect structure;

FIGS. 5a-5b illustrate disposing the interposer and semiconductor die over a package substrate; and

FIG. 6 illustrates a printed circuit board (PCB) with different types of packages disposed on a surface of the PCB.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The features shown in the figures are not necessarily drawn to scale. Elements having a similar function are assigned the same reference number in the figures. The term “semiconductor die” as used herein refers to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. TO singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

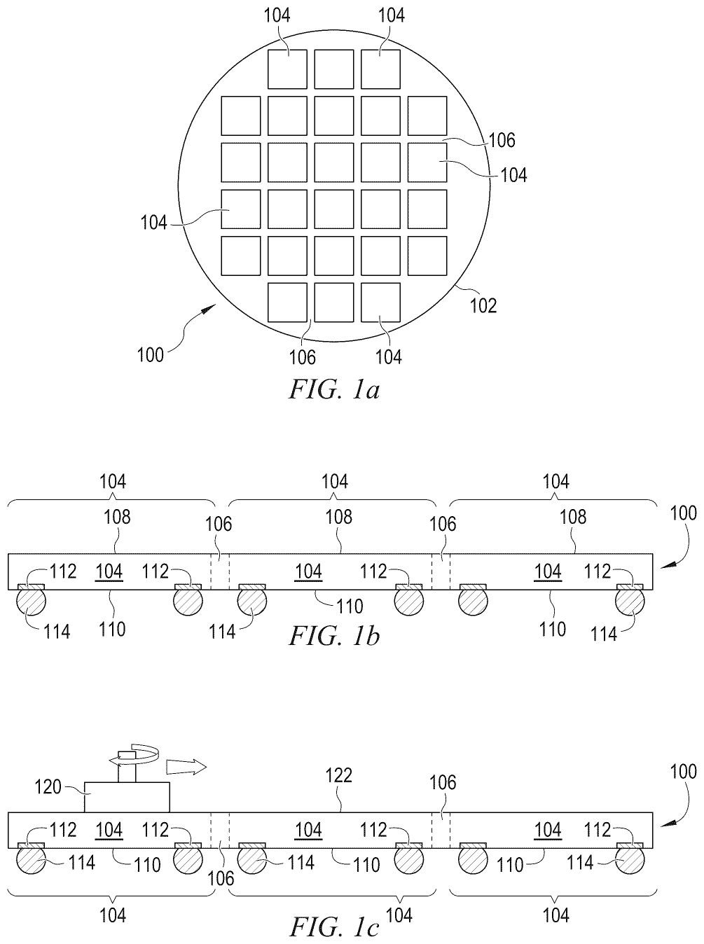

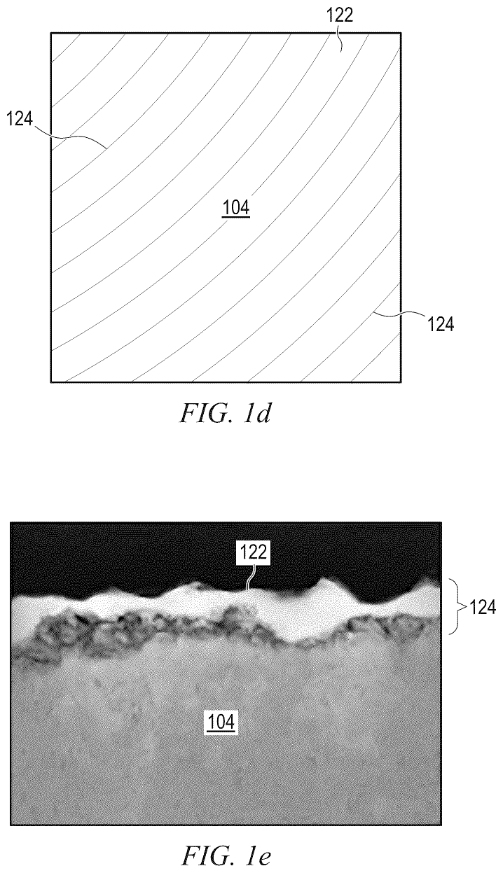

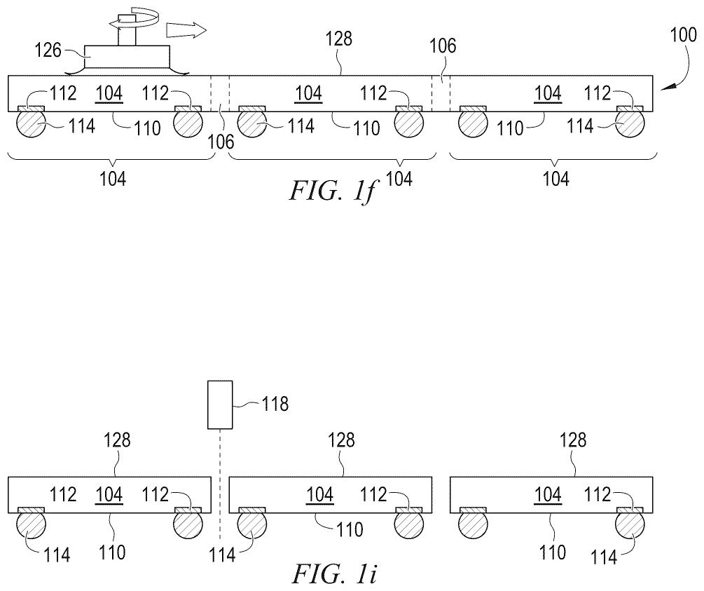

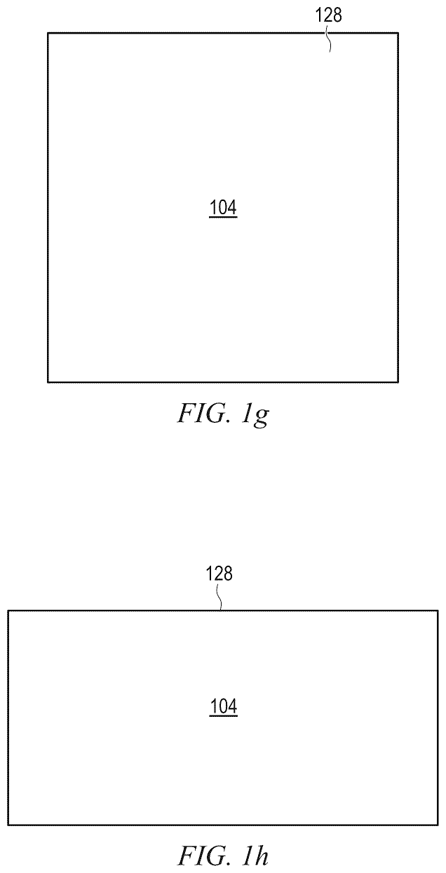

FIG. 1a shows a semiconductor wafer 100 with a base substrate material 102, such as silicon, germanium, aluminum phosphide, aluminum arsenide, gallium arsenide, gallium nitride, indium phosphide, silicon carbide, or other bulk material for structural support. A plurality of semiconductor die or electrical components 104 is formed on wafer 100 separated by a non-active, inter-die wafer area or saw street 106. Saw street 106 provides cutting areas to singulate semiconductor wafer 100 into individual semiconductor die 104. In one embodiment, semiconductor wafer 100 has a width or diameter of 100-450 millimeters (mm).

FIG. 1b shows a cross-sectional view of a portion of semiconductor wafer 100. Each semiconductor die 104 has a back surface 108 and an active surface 110 containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active surface 110 to implement analog circuits or digital circuits, such as digital signal processor (DSP), application specific integrated circuits (ASIC), memory, or other signal processing circuit. Semiconductor die 104 may also contain IPDs, such as inductors, capacitors, and resistors, for RF signal processing. In one embodiment, semiconductor die 104 is a MEMS device. For example, semiconductor die 104 may have a sensor, e.g., pressure or temperature sensor, formed on back surface 108 and active sensor interface components formed on active surface 110.

An electrically conductive layer 112 is formed over active surface 110 using PVD, CVD, electrolytic plating, electroless plating process, or other suitable metal deposition process. Conductive layer 112 can be one or more layers of aluminum (Al), copper (Cu), tin (Sn), nickel (Ni), gold (Au), silver (Ag), or other suitable electrically conductive material. Conductive layer 112 operates as contact pads electrically connected to the circuits on active surface 110.

An electrically conductive bump material is deposited over conductive layer 112 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 112 using a suitable attachment or bonding process. In one embodiment, the bump material is reflowed by heating the material above its melting point to form balls or bumps 114. In one embodiment, bump 114 is formed over an under bump metallization (UBM) having a wetting layer, barrier layer, and adhesive layer. Bump 114 can also be compression bonded or thermocompression bonded to conductive layer 112. Bump 114 represents one type of interconnect structure that can be formed over conductive layer 112. The interconnect structure can also use bond wires, conductive paste, stud bump, micro bump, or other electrical interconnect.

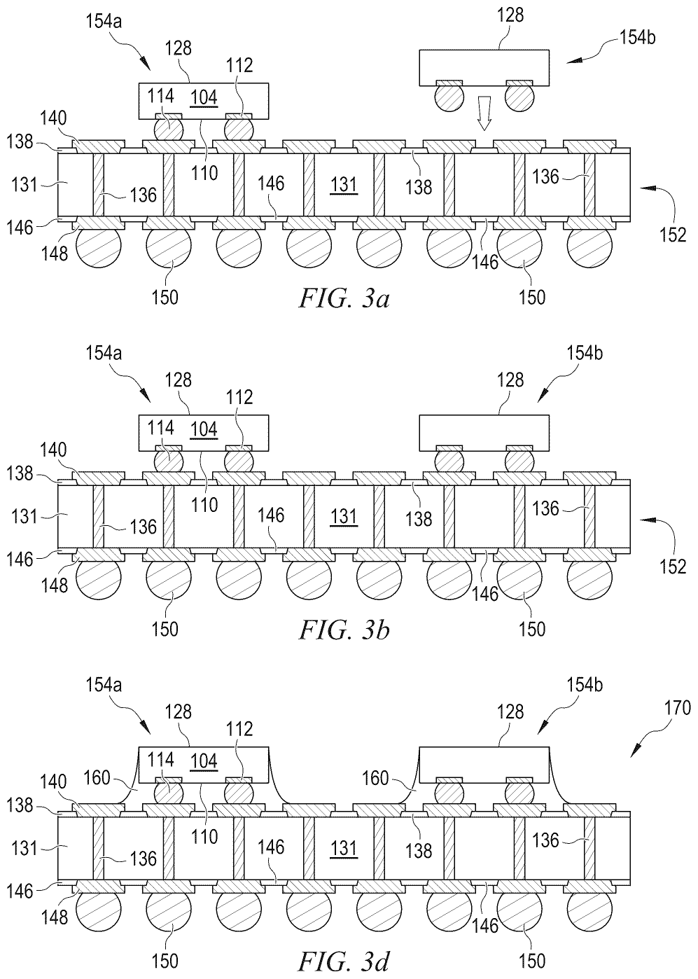

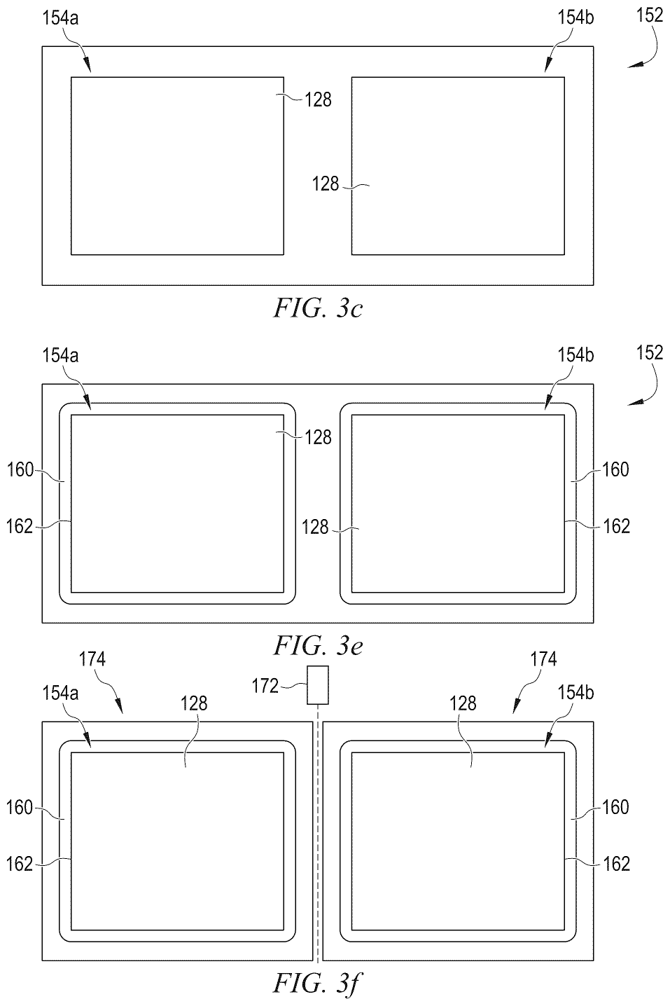

Semiconductor wafer 100 and semiconductor die 104 may be considered a thin device, e.g., <120.0 μm in thickness. Semiconductor die 104 may be used in chip-on-wafer (CoW) process for small devices, described in detail infra. In FIG. 1c, semiconductor wafer 100 is inverted and back surface 108 undergoes a grinding operation with grinder 120 to remove surface roughness. The grinding operation nonetheless leaves grooves, scratches, and other damage 124 in surface 122, as shown in the top view of semiconductor die 104 in FIG. 1d. FIG. 1e is a cross-sectional view of grooves, scratches, and other damage 124 in surface 122. The grooves, scratches, and other damage 124 can have a depth of 100.0 nanometers. The grooves, scratches, and other damage 124 in surface 122 can lead to underfill creeping to surface 122, as discussed in FIG. 3d. The underfill creeping introduces epoxy and other contaminants to surface 122. The underfill creeping can leave epoxy and other contaminants in the grooves, scratches, and other damage 124 in surface 122. The underfill contamination adversely affects the functional performance of semiconductor die 104 as a MEMS device. For example, the underfill creeping can cause defects in the back surface sensor of semiconductor die 104.

In FIG. 1f, surface 122 is polished with polisher 126 to remove grooves, scratches, and other damage 124 from surface 122. The polishing may involve dry polish, chemical mechanical polish, dry etching, and other suitable polishing process leaving surface 128 with a smooth, mirror-like finish. FIG. 1g is a top view of the smooth, mirror-like finish of surface 128. FIG. 1h is a cross-sectional view of the smooth, mirror-like finish of surface 128, with grooves, scratches, and other damage 124 having been removed by the polishing process.

In FIG. 1i, semiconductor wafer 100 is singulated through saw street 106 using a saw blade or laser cutting tool 129 into individual semiconductor die 104. The individual semiconductor die 104 can be inspected and electrically tested for identification of known good die or known good unit (KGD/KGU) post singulation. In particular, semiconductor die 104 have a smooth, mirror-like finish on surface 128 from the polishing process of FIGS. 1f-1h. Semiconductor die 104 may have small dimensions, e.g., 0.4 mm×0.4 mm.

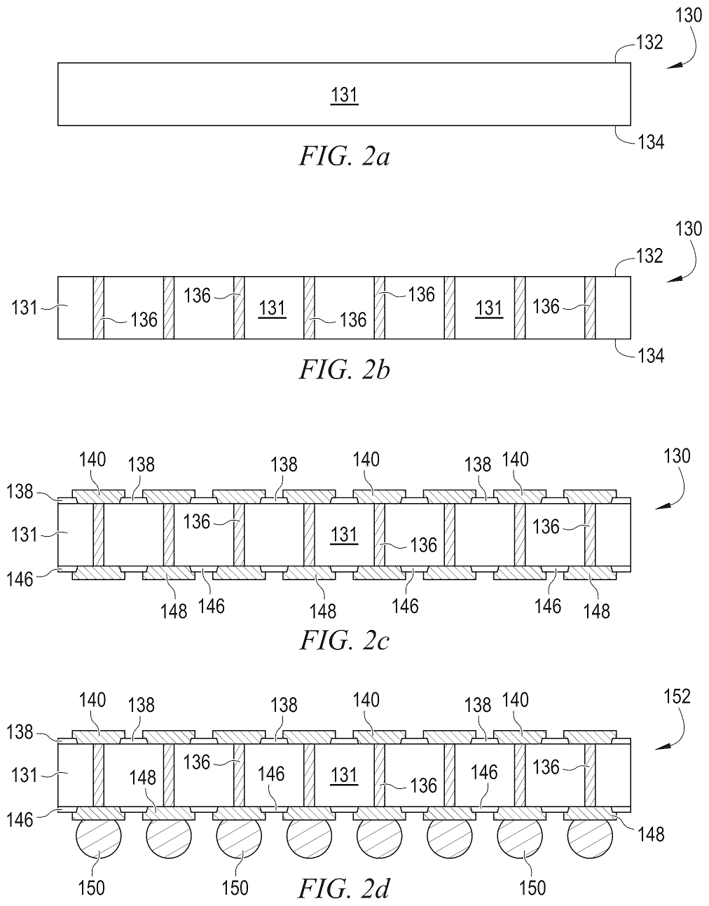

FIG. 2a shows a substrate or interposer 130 made with base material 131, such as silicon, germanium, aluminum phosphide, aluminum arsenide, gallium arsenide, gallium nitride, indium phosphide, silicon carbide, or other bulk material for structural support. Substrate 130 has major surface 132 and major surface 134, opposite surface 132.

In FIG. 2b, a plurality of vias is formed through substrate 130 using an etching process or laser direct ablation (LDA). The vias are filled with conductive material to form conductive vias 136 extending between surface 132 and surface 134 of substrate 130.

In FIG. 2c, an insulating or passivation layer 138 is formed over surface 132 using PVD, CVD, printing, lamination, spin coating, spray coating, sintering or thermal oxidation. Insulating layer 138 contains one or more layers of silicon dioxide (SiO2), silicon nitride (Si3N4), silicon oxynitride (SiON), tantalum pentoxide (Ta2O5), aluminum oxide (Al2O3), solder resist, polyimide, benzocyclobutene (BCB), polybenzoxazoles (PBO), and other material having similar insulating and structural properties. Portions of insulating layer 138 are removed using an etching process or LDA to form openings or vias extending to conductive vias 136 for further electrical interconnect.

A conductive layer 140 is formed over insulating layer 138 using PVD, CVD, electrolytic plating, electroless plating process, or other suitable metal deposition process. Conductive layer 140 can be one or more layers of Al, Cu, Sn, Ni, Au, Ag, or other suitable electrically conductive material. Conductive layer 140 extends through the openings in insulating layer 138 to conductive vias 136. Conductive layer 140 functions as a redistribution layer (RDL) providing electrical interconnect across substrate 130.

An insulating or passivation layer 146 is formed over surface 134 using PVD, CVD, printing, lamination, spin coating, spray coating, sintering or thermal oxidation. Insulating layer 146 contains one or more layers of SiO2, Si3N4, SiON, Ta2O5, Al2O3, solder resist, polyimide, BCB, PBO, and other material having similar insulating and structural properties. Portions of insulating layer 146 are removed using an etching process or LDA to form openings or vias extending to conductive vias 136 for further electrical interconnect.

A conductive layer 148 is formed over insulating layer 146 using PVD, CVD, electrolytic plating, electroless plating process, or other suitable metal deposition process. Conductive layer 140 can be one or more layers of Al, Cu, Sn, Ni, Au, Ag, or other suitable electrically conductive material. Conductive layer 148 extends through the openings in insulating layer 146 to conductive vias 136. Additional insulating layers like 138 and 146 and conductive layers like 140 and 148 can be formed over surface 132 and surface 134, respectively. Conductive layer 148 functions as an RDL providing electrical interconnect across substrate 130. Accordingly, portions of conductive layer 140 are connected to portions of conductive layer 148 through conductive vias 136.

In FIG. 2d, an electrically conductive bump material is deposited over conductive layer 148 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 148 using a suitable attachment or bonding process. In one embodiment, the bump material is reflowed by heating the material above its melting point to form balls or bumps 150. In one embodiment, bump 150 is formed over a UBM having a wetting layer, barrier layer, and adhesive layer. Bump 150 can also be compression bonded or thermocompression bonded to conductive layer 148. Bump 150 represents one type of interconnect structure that can be formed over conductive layer 148. The interconnect structure can also use bond wires, conductive paste, stud bump, micro bump, or other electrical interconnect.

The combination of substrate 130, conductive vias 136, insulating layers 138 and 146, conductive layers 140 and 148, and bumps 150 constitute bumped base wafer or interposer 152.

In FIG. 3a, electrical components 154a-154b are disposed over surface 132 of substrate 130. Electrical components 154a-154b are disposed over bumped base wafer 152 with bumps 114 oriented toward bumped base wafer 152 and polished back surface 128 oriented away from the bumped base wafer. Electrical component 154a-154b can be semiconductor die 104 from FIG. 1i. Alternatively, electrical components 154a-154b can include other semiconductor die, semiconductor packages, surface mount devices, RF components, discrete electrical devices, or integrated passive devices (IPD).

Electrical components 154a-154b are positioned over conductive layer 140 of bumped base wafer 152 using a pick and place operation. Electrical components 154a-154b are brought into contact with conductive layer 140 and reflowed to make mechanical and electrical connection to bumped base wafer 152. FIG. 3b illustrates electrical components 154a-154b bonded to conductive layer 140 of bumped base wafer 152. FIG. 3c is a top view of electrical components 154a-154b bonded to conductive layer 140 of bumped base wafer 152, as CoW 170. The bumped base wafer 152 can be cleaned and subject to automated optical inspection (AOI).

In FIG. 3d, an underfill material 160 is deposited around and under electrical components 154a-154b. Underfill material 160 can be an epoxy resin. FIG. 3e is a top view of underfill material 160 deposited around and under electrical components 154a-154b. Back surface 128 of electrical components 154a-154b may contain components of a MEMS device, such as a sensor described in FIG. 1b. It is important that underfill material 160 does not creep on back surface 128. Underfill material 160 creeping onto back surface 128 may be considered as cosmetic defect. Also, the underfill material 160 may cover laser marking areas on back surface 128.

The polished back surface 128, as described in FIGS. 1f-1h, prevents underfill material 160 from progressing or creeping onto polished back surface 128. With the polished back surface 128, underfill material 160 does not extend past edge or boundary 162. The polished back surface 128 inhibits the creep or progression of underfill material 160 over the back surface of the semiconductor die. Back surface 128 of electrical components 154a-154b, due to its smooth, mirror-like finish, remains free of contaminates and other defects from potential creep of underfill material 160. Underfill material 160 is cured and the bumped base wafer 152 subjected to AOI.

In FIG. 3f, CoW 170 is singulated through substrate 152 using a saw blade or laser cutting tool 172 into individual semiconductor packages 174. The individual semiconductor packages 174 can be inspected and electrically tested for identification of KGD/KGU post singulation.

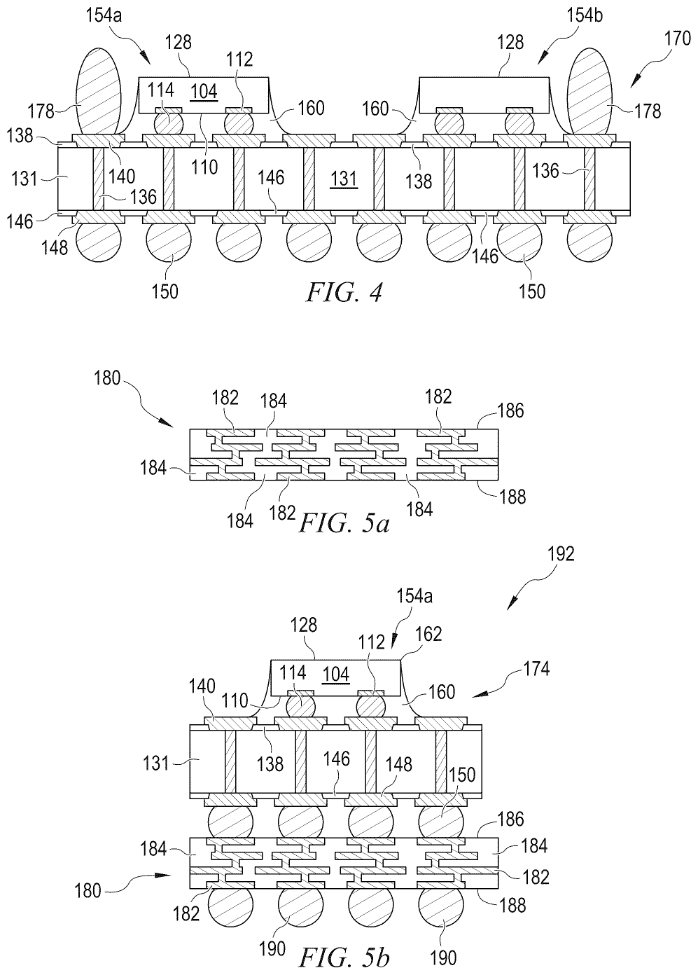

FIG. 4 illustrates an embodiment, similar to FIG. 3d, with interconnect structures 178 formed over conductive layer 140. The polished back surface 128 inhibits the creep or progression of underfill material 160 over the back surface of the semiconductor die to avoid accumulation of underfill material on the back surface that could interfere with interconnect structures 178 making contact with other external devices. Underfill material 160 should not be higher than the top of interconnect structures 178.

FIG. 5a shows a cross-sectional view of package-level interconnect substrate 180 including conductive layers 182 and insulating layer 184. Conductive layer 182 can be one or more layers of Al, Cu, Sn, Ni, Au, Ag, or other suitable electrically conductive material. Conductive layers 182 can be formed using PVD, CVD, electrolytic plating, electroless plating process, or other suitable metal deposition process. Conductive layer 182 provides horizontal electrical interconnect across substrate 180 and vertical electrical interconnect between top surface 186 and bottom surface 188 of substrate 180. Portions of conductive layer 182 can be electrically common or electrically isolated depending on the design and function of semiconductor die 104 and other electrical components. Insulating layer 184 contains one or more layers of SiO2, Si3N4, SiON, Ta2O5, Al2O3, solder resist, polyimide, BCB, PBO, and other material having similar insulating and structural properties. Insulating layers 184 can be formed using PVD, CVD, printing, lamination, spin coating, spray coating, sintering or thermal oxidation. Insulating layer 184 provides isolation between conductive layers 182. There can be multiple conductive layers like 182 separated by multiple insulating layers like 184.

In FIG. 5b, semiconductor package 174 is mounted to substrate 180 using a pick and place operation, similar to FIGS. 3a-3b. An electrically conductive bump material is deposited over conductive layer 182 on surface 188 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 182 using a suitable attachment or bonding process. In one embodiment, the bump material is reflowed by heating the material above its melting point to form balls or bumps 190. In another embodiment, bump 190 is formed over a UBM having a wetting layer, barrier layer, and adhesive layer. Bump 190 can also be compression bonded or thermocompression bonded to conductive layer 182. Bump 190 represents one type of interconnect structure that can be formed over conductive layer 182. The interconnect structure can also use conductive paste, stud bump, micro bump, or other electrical interconnect.

The combination of semiconductor package 174 and package-level substrate 180 constitutes semiconductor package 192. The polished back surface 128, as described in FIGS. 1f-1h, prevents underfill material 160 from progressing or creeping onto polished back surface 128. With the polished back surface 128, underfill material 160 does not extend past edge or boundary 162. The polished back surface 128 inhibits the creep or progression of underfill material over the back surface of the semiconductor die. Back surface 128 of electrical components 154a-154b, due to its smooth, mirror-like finish, remains free of contaminates and other defects from potential creep of underfill material 160.

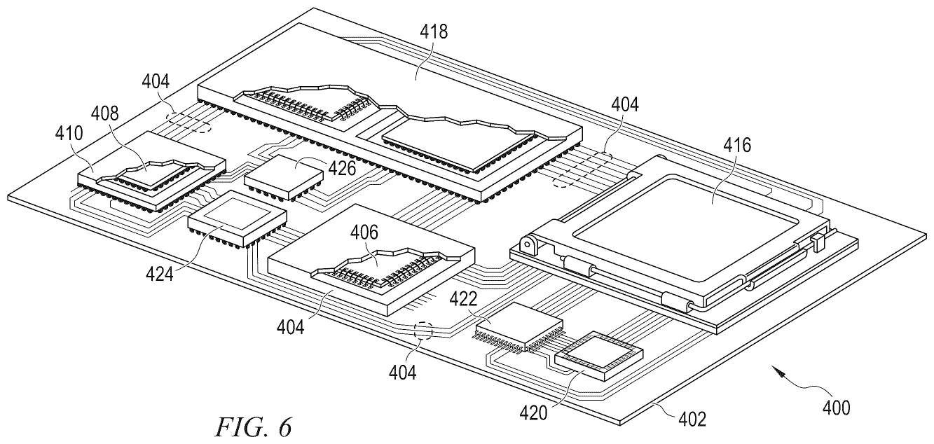

FIG. 6 illustrates electrical device 400 having a chip carrier substrate or PCB 402 with a plurality of semiconductor packages disposed on a surface of PCB 402, including semiconductor packages 174 and 192. Electrical device 400 can have one type of semiconductor package, or multiple types of semiconductor packages, depending on the application.

Electrical device 400 can be a stand-alone system that uses the semiconductor packages to perform one or more electrical functions. Alternatively, electrical device 400 can be a subcomponent of a larger system. For example, electrical device 400 can be part of a tablet, cellular phone, digital camera, communication system, or other electrical device. Alternatively, electrical device 400 can be a graphics card, network interface card, or other signal processing card that can be inserted into a computer. The semiconductor package can include microprocessors, memories, ASIC, logic circuits, analog circuits, RF circuits, discrete devices, or other semiconductor die or electrical components. Miniaturization and weight reduction are essential for the products to be accepted by the market. The distance between semiconductor devices may be decreased to achieve higher density.

In FIG. 6, PCB 402 provides a general substrate for structural support and electrical interconnect of the semiconductor packages disposed on the PCB. Conductive signal traces 404 are formed over a surface or within layers of PCB 402 using evaporation, electrolytic plating, electroless plating, screen printing, or other suitable metal deposition process. Signal traces 404 provide for electrical communication between each of the semiconductor packages, mounted components, and other external system components. Traces 404 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may have the first level packaging where the die is mechanically and electrically disposed directly on the PCB. For the purpose of illustration, several types of first level packaging, including bond wire package 406 and flipchip 408, are shown on PCB 402. Additionally, several types of second level packaging, including ball grid array (BGA) 410, bump chip carrier (BCC) 412, land grid array (LGA) 416, multi-chip module (MCM) or SIP module 418, quad flat non-leaded package (QFN) 420, quad flat package 422, embedded wafer level ball grid array (eWLB) 424, and wafer level chip scale package (WLCSP) 426 are shown disposed on PCB 402. In one embodiment, eWLB 424 is a fan-out wafer level package (Fo-WLP) and WLCSP 426 is a fan-in wafer level package (Fi-WLP). Depending upon the system requirements, any combination of semiconductor packages, configured with any combination of first and second level packaging styles, as well as other electrical components, can be connected to PCB 402. In some embodiments, electrical device 400 includes a single attached semiconductor package, while other embodiments call for multiple interconnected packages. By combining one or more semiconductor packages over a single substrate, manufacturers can incorporate pre-made components into electrical devices and systems. Because the semiconductor packages include sophisticated functionality, electrical devices can be manufactured using less expensive components and a streamlined manufacturing process. The resulting devices are less likely to fail and less expensive to manufacture resulting in a lower cost for consumers.

While one or more embodiments of the present invention have been illustrated in detail, the skilled artisan will appreciate that modifications and adaptations to those embodiments may be made without departing from the scope of the present invention as set forth in the following claims.

What is claimed:

1. A method of making a semiconductor device, comprising:
providing a first substrate;
polishing a surface of the first substrate to produce a polished surface;
singulating the first substrate into a plurality of semiconductor die;
providing an interposer;
disposing the semiconductor die over the interposer; and
depositing an underfill material around the semiconductor die, wherein the polished surface inhibits progression of the underfill material onto the surface of the substrate.

2. The method of claim 1, further including grinding the surface of the substrate prior to polishing the surface of the substrate.

3. The method of claim 1, wherein providing the interposer includes:
providing a second substrate; and
forming a conductive via through the second substrate.

4. The method of claim 3, wherein providing the interposer further includes:
forming a first insulating layer over a first surface of the second substrate; and
forming a first conductive layer over the first surface of the second substrate.

5. The method of claim 4, wherein providing the interposer further includes:
forming a second insulating layer over a second surface of the second substrate opposite the first surface of the second substrate;
forming a second conductive layer over the second surface of the second substrate; and
forming a bump over the second conductive layer.

6. The method of claim 1, wherein a thickness of the first substrate is less than 120 micrometers.

7. A method of making a semiconductor device, comprising:
providing a first substrate;
polishing a surface of the first substrate to produce a polished surface;
singulating the first substrate into a plurality of semiconductor die; and
depositing an underfill material around the semiconductor die, wherein the polished surface inhibits progression of the underfill material onto the surface of the substrate.

8. The method of claim 7, further including grinding the surface of the substrate prior to polishing the surface of the substrate.

9. The method of claim 7, further including:
providing an interposer; and
disposing the semiconductor die over the interposer.

10. The method of claim 9, wherein providing the interposer includes:
providing a second substrate; and
forming a conductive via through the second substrate.

11. The method of claim 10, wherein providing the interposer further includes:
forming a first insulating layer over a first surface of the second substrate; and
forming a first conductive layer over the first surface of the second substrate.

12. The method of claim 11, wherein providing the interposer further includes:
forming a second insulating layer over a second surface of the second substrate opposite the first surface of the second substrate;
forming a second conductive layer over the second surface of the second substrate; and
forming a bump over the second conductive layer.

13. The method of claim 7, wherein a thickness of the first substrate is less than 120 micrometers.

14. A semiconductor device, comprising:
a semiconductor die including a polished surface;
an interposer with the semiconductor die disposed over the interposer; and
an underfill material deposited around the semiconductor die, wherein the polished surface inhibits progression of the underfill material onto the polished surface of the semiconductor die.

15. The semiconductor device of claim 14, wherein the interposer includes:
a substrate; and
a conductive via through the substrate.

16. The semiconductor device of claim 15, wherein the interposer further includes:
a first insulating layer formed over a first surface of the substrate; and
a first conductive layer formed over the first surface of the substrate.

17. The semiconductor device of claim 16, wherein the interposer further includes:
a second insulating layer formed over a second surface of the second substrate opposite the first surface of the second substrate;
a second conductive layer formed over the second surface of the second substrate; and
a bump formed over the second conductive layer.

18. The semiconductor device of claim 14, wherein a thickness of the semiconductor die is less than 120 micrometers.

19. The semiconductor device of claim 14, further including a package substrate, wherein the interposer and semiconductor die are disposed over the package substrate.

20. A semiconductor device, comprising:
a semiconductor die including a polished surface; and
an underfill material deposited around the semiconductor die, wherein the polished surface inhibits progression of the underfill material onto the polished surface of the semiconductor die.

21. The semiconductor device of claim 20, further including an interposer with the semiconductor die disposed over the interposer.

22. The semiconductor device of claim 21, wherein the interposer includes:
a substrate; and
a conductive via through the substrate.

23. The semiconductor device of claim 22, wherein the interposer further includes:
a first insulating layer formed over a first surface of the substrate; and
a first conductive layer formed over the first surface of the substrate.

24. The semiconductor device of claim 23, wherein the interposer further includes:
a second insulating layer formed over a second surface of the second substrate opposite the first surface of the second substrate;
a second conductive layer formed over the second surface of the second substrate; and
a bump formed over the second conductive layer.

25. The semiconductor device of claim 20, wherein a thickness of the semiconductor die is less than 120 micrometers.
